(19) United States
(12) Patent Application Publication
(10) Pub. No.: US 2024/0405749 A1
(43) Pub. Date: Dec. 5, 2024

(54) HIGH-FREQUENCY FILTER DEVICE, HIGH-FREQUENCY MODULE, AND HIGH-FREQUENCY FILTER METHOD

(71) Applicant: Robert Bosch GmbH, Stuttgart (DE)

(72) Inventor: Christoph Schelling, Stuttgart (DE)

(21) Appl. No.: 18/699,043

(22) PCT Filed: Oct. 5, 2022
(86) PCT No.: PCT/EP2022/077669

§ 371 Date: Apr. 5, 2024

(30) Foreign Application Priority Data
Oct. 29, 2021 (DE) 10 2021 212 216.7

(51) Int. Cl. H03H 9/64; H03H 9/05; H03H 9/54

(52) U.S. Cl. CPC H03H 9/6483; H03H 9/0542; H03H 9/545; H03H 9/6403

(57) ABSTRACT

A high-frequency filter device. The high-frequency filter device includes a signal input, which is designed to receive a high-frequency signal. The high-frequency filter device also includes a plurality of filter units, which are designed to filter the high-frequency signal received by the signal input. The high-frequency filter device also includes at least one switch unit, which can be actuated by a switch signal in order to modify a filter characteristic of the high-frequency filter device by connecting the filter units. The high-frequency filter device includes a signal output, which is designed to output the filtered high-frequency signal.

### FIELD

The present invention relates to a high-frequency filter device, a high-frequency module and a high-frequency filter method.

### BACKGROUND INFORMATION

A large number of high-frequency filter components are used in today's mobile devices with mobile communications in order to enable the best possible network connection anywhere in the world and to be able to use a high bandwidth for data transmission. As a result, there is ever-increasing demand for high-frequency filter components, which means that the size of the high-frequency front-end modules in which the high-frequency filter components are integrated will continue to grow and their energy consumption will increase.

U.S. Patent No. U.S. Pat. No. 10,326,200 B2 relates to high-frequency communication systems, wherein a plurality of signal transmission paths connected in parallel are provided, which can be switched on and off via switch elements.

### SUMMARY

The present invention provides a high-frequency filter device, a high-frequency module and a high-frequency filter method.

Preferred embodiments of the present invention are disclosed herein.

According to a first aspect, the present invention relates to a high-frequency filter device comprising a signal input, which is designed to receive a high-frequency signal. The high-frequency filter device also comprises a plurality of filter units, which are designed to filter the high-frequency signal received by the signal input. The high-frequency filter device also comprises at least one switch unit, which can be actuated by a switch signal in order to modify a filter characteristic of the high-frequency filter device by connecting the filter units. The high-frequency filter device comprises a signal output, which is designed to output the filtered high-frequency signal.

According to a second aspect, the present invention relates to a high-frequency module comprising at least one high-frequency filter device according to the present invention and a control unit for actuating the switch unit of the high-frequency filter device by a switch signal.

According to a third aspect, the present invention relates to a high-frequency filter method. A high-frequency signal is received and filtered by means of a plurality of filter units. The filtered high-frequency signal is output. By actuating a switch unit by means of a switch signal, the filter devices are connected in such a way that a filter characteristic of the high-frequency filter device is modified.

The present invention provides a configurable high-frequency filter device that can be used as a component in high-frequency modules. By providing a plurality of filter units that can be interconnected, even a single high-frequency filter device can enable different filter characteristics. This means that the number of high-frequency filter devices required can be reduced. By requiring fewer discrete high-frequency filter devices, the overall size of the high-frequency module can also be reduced. Finally, energy can also be saved.

Furthermore, when used in the mobile communications sector, it is possible to take local network conditions into account accordingly by flexible reconfiguration of the filter units during operation.

According to a further embodiment of the high-frequency filter device of the present invention, each filter unit can comprise a plurality of firmly interconnected acoustic resonators, which form, for example, a ladder configuration and/or a lattice configuration.

According to a further embodiment of the high-frequency filter device of the present invention, the filter units are connected in series or partially in parallel by the switch signal. As a result, different filter characteristics can be set.

According to a further embodiment of the high-frequency filter device of the present invention, the at least one switch unit is designed as a microelectromechanical, MEMS, switch unit. This has the advantage that, due to the low masses, switching between different signal conduction paths can be carried out very quickly, with a high degree of linearity, low losses-both in terms of signal losses and switching power losses-and with a high switch-on current (Iₒₙ) to switch-off current (I_{off}) ratio. The control of the MEMS switch unit can advantageously be undertaken by an external controller circuit, wherein the high-frequency filter device itself need not have any integrated digital or analog transistor circuits. The high degree of linearity of the MEMS switch unit is particularly advantageous in the mm-wave range at frequencies above 20-30 GHz.

According to a further embodiment of the high-frequency filter device of the present invention, the MEMS switch unit can be actuated electrostatically and/or piezoelectrically by the switch signal. Both actuation mechanisms are particularly low-loss and technologically related to the transducer principles of the filter units themselves, such that synergies arise upon production, such as the use of at least one common electrode layer made of the same material (for example, tungsten or molybdenum) for both the MEMS switch unit and the acoustic filter unit.

According to a further embodiment of the high-frequency filter device of the present invention, the MEMS switch unit has at least one electrode layer, which consists of the same material as a layer of the filter units. As a result, a compact structure is possible.

According to a further embodiment of the high-frequency filter device of the present invention, the modified filter characteristic is at least one of a passband width, a phase position and an impedance of the high-frequency filter device. As a result, simple adjustments to local requirements can be carried out in the mobile communications sector, for example.

According to a further embodiment of the present invention, the high-frequency filter device comprises a control line, which is designed to receive the externally generated switch signal and transmit it to the switch unit for actuating the switch unit. According to further embodiments, the switch signal can also be generated by an internal control unit, i.e. the control unit is integrated into the high-frequency filter device.

According to a further embodiment of the high-frequency filter device of the present invention, the filter units in each case comprise a surface-acoustic or volume-acoustic resonator based on piezo materials such as AlN, Sc₁₋ₓAₓN, LiNbO₃, LiTaO₃, etc. Alternatively or additionally, the filter units comprise at least one capacitor and/or at least one resistor. The high-frequency filter device can additionally network a plurality of filter elements, resistors, capacitors and inductors in a circuit on a substrate to represent desired transmission characteristics (such as impedance, band-pass range or phase).

According to a further embodiment of the high-frequency filter device of the present invention, the filter units have individual narrow-band band-pass characteristics, which can add up to a wider-band band-pass characteristic in a suitable switch position.

According to a further embodiment of the high-frequency filter device of the present invention, the acoustic resonators of the filter units in each case have a piezo element, which is designed as a single-layer or multi-layer piezo stack. The multi-layer piezo stack can comprise, for example, (Scₓ)Al₁₋ₓN, 0≤x<0.45, with identical or alternating polarity or composition.

According to a further embodiment of the high-frequency filter device of the present invention, the acoustic resonators of the filter units have electrode layers comprising acoustic Bragg reflector stacks, for example multi-layer stacks with alternating high and low acoustic impedance, for example made of titanium, tungsten or molybdenum. In this way, losses of acoustic energy in the acoustic resonators are prevented and the signal intensity is maintained.

Further advantages, features and details of the present invention will become apparent from the following description, in which various exemplary embodiments are described in detail with reference to the figures.

### BRIEF DESCRIPTION OF THE DRAWINGS

FIG. 1 shows a schematic block diagram of a high-frequency module according to one example embodiment of the present invention.

FIG. 2 shows a schematic block diagram of a high-frequency filter device according to one example embodiment of the present invention.

FIG. 3 shows a schematic block diagram of a high-frequency filter device according to a further example embodiment of the present invention.

FIG. 4 shows a schematic block diagram of a high-frequency filter device according to a further example embodiment of the present invention.

FIG. 5 shows a schematic cross-sectional view of a high-frequency filter device according to an exemplary embodiment of the present invention.

FIG. 6 shows a flow chart of a high-frequency filtering method according to one example embodiment of the present invention.

### DETAILED DESCRIPTION OF EXAMPLE EMBODIMENTS

In all figures, identical or functionally identical elements and devices are provided with the same reference signs. The numbering of method steps serves the purpose of clarity and is generally not intended to imply a specific chronological order. In particular, a plurality of method steps may also be carried out simultaneously.

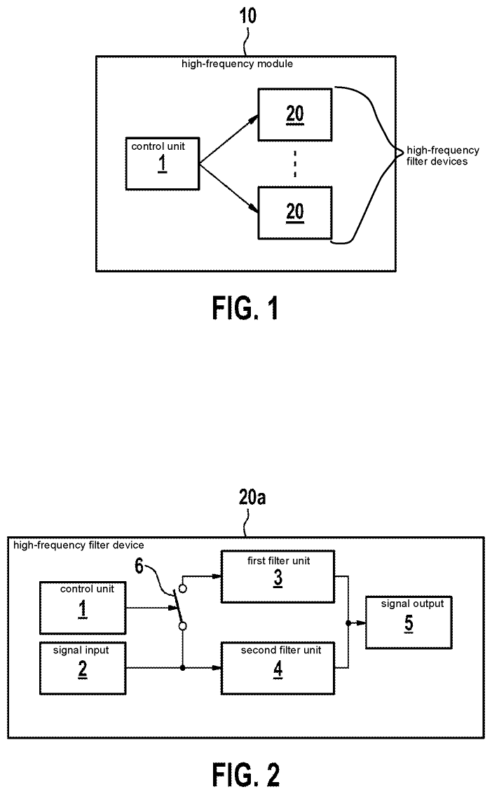

FIG. 1 shows a schematic block diagram of a high-frequency module 10. The high-frequency module 10 can be used in the mobile communications sector, for example, to filter received signals. The high-frequency module 10 comprises high-frequency filter devices 20 and a control unit 1 for actuating a switch unit of the high-frequency filter devices 20 by a switch signal.

The switch unit can be a discrete MEMS switch that is actuated by a control line via a circuit in the control unit 1 to control the switch unit. Preferably, switch units can alternatively be integrated into the high-frequency filter devices 20.

Furthermore, the high-frequency module 10 can have a high-frequency front-end ASIC (RFIC; application-specific integrated circuit for processing radio signals), amplifier and the like.

The high-frequency filter devices 20 can be one of the following exemplary high-frequency filter devices 20 described in FIGS. 2 to 5.

FIG. 2 shows a schematic block diagram of a high-frequency filter device 20a comprising a signal input 2 for receiving a high-frequency signal. The high-frequency filter device 20a also comprises a first filter unit 3 and a second filter unit 4, which in each case have an input and an output and filter the signal received via the input. The filter units 3, 4 can be high-pass filters, low-pass filters or band-pass filters, for example.

The high-frequency filter device 20a also comprises a switch unit 6, which is controlled by a control unit 1 by means of a switch signal. While the control unit 1 is integrated into the high-frequency filter device 20a in FIG. 2, the control unit 1 can also be arranged externally, for example to control a plurality of high-frequency filter devices 20a, as shown in FIG. 1.

If the switch unit 6 is open, the high-frequency signal is only filtered by the second filter unit 4 and output via a signal output 5.

If the switch unit 6 is closed, the high-frequency signal is additionally filtered by the first filter unit 3 connected in parallel and the signal filtered by the first filter unit 3 is combined with the signal filtered by the second filter unit 4 and output as an output signal via the signal output 5.

The filter properties of the first filter unit 3 can differ from the filter properties of the second filter unit 4. For example, in each case these can be band-pass filters that filter different frequency ranges. By switching on the first filter unit 3, the transmitted frequency range can be increased.

The filter properties of the first filter unit 3 and the second filter unit 4 can also be identical. When the first filter unit 3 is switched on, the total resistance changes, which also leads to a change in the filter characteristics of the high-frequency filter device 20a.

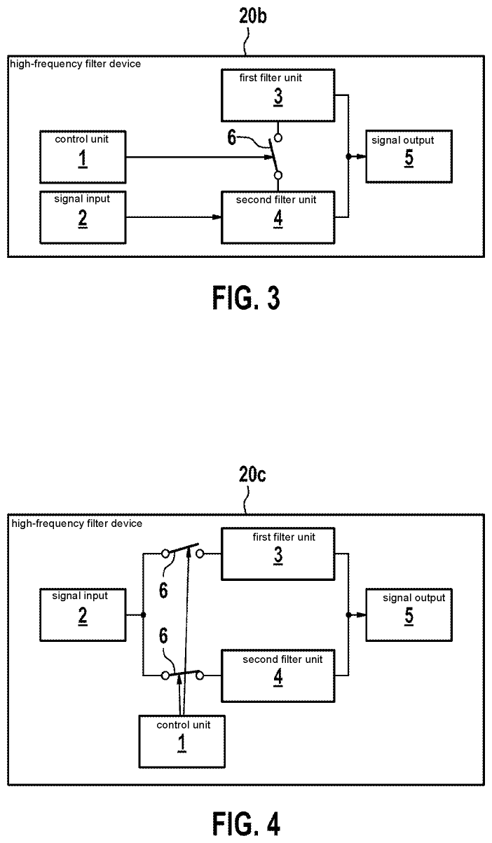

FIG. 3 shows a schematic block diagram of a further high-frequency filter device 20b. The circuit differs from the circuit illustrated in FIG. 2 in that the input signal is first filtered by the second filter unit 4 before it can be provided to the first filter unit 3 via a switch unit 6. The first filter unit 3 can, for example, displace a phase of the applied signal. When the switch unit 6 is closed, the signal filtered by the second filter unit 4 is combined with the signal filtered by both the second filter unit 4 and the first filter unit 3 and output as an output signal at the signal output 5. When the switch unit 6 is open, the signal filtered only by the second filter unit 4 is output as an output signal.

FIG. 4 shows a schematic block diagram of a further high-frequency filter device 20c. The circuit differs from the circuit illustrated in FIG. 2 in that two switch units 6 are provided. As a result, both the first switch unit 3 and the second switch unit 4 can be switched to be activated or deactivated. The switch units 6 can be switched independently of one another, so that four filter characteristics can be set.

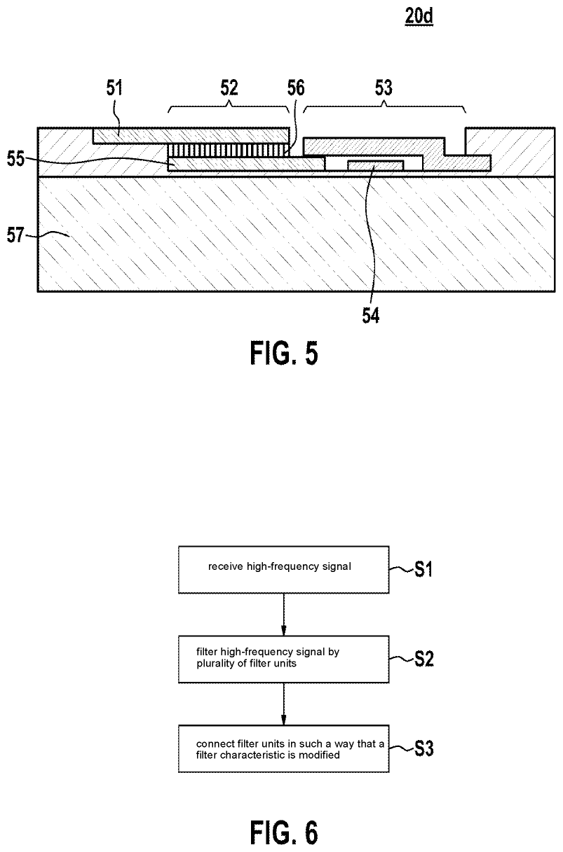

FIG. 5 shows a schematic cross-sectional view of a high-frequency filter device 20d. This comprises a substrate 57 on which an acoustic resonator 52 is arranged as part of a filter unit. This comprises an upper electrode 51, a lower electrode 55 and a piezo element 56 located between them. The high-frequency filter device 20d also comprises a MEMS switch unit 53 with a control electrode 54. The piezo element 56 is designed as a multi-layer piezo stack.

FIG. 6 shows a flow chart of a high-frequency filter method. The method can be carried out by means of one of the high-frequency filter devices 20; 20a-20d described above.

In a first method step S1, a high-frequency signal is received. The high-frequency signal is filtered in a second method step S2 by means of a plurality of filter units 3, 4. The filtered high-frequency signal is output. By actuating a switch unit 6 by a switch signal, the filter units 3, 4 are connected in a third method step S3 in such a way that a filter characteristic of the high-frequency filter device 20; 20a-d is modified

1-10. (canceled)

11. A high-frequency filter device, comprising:
a signal input which is configured to receive a high-frequency signal;
a plurality of filter units which are configured to filter the high-frequency signal received by the signal input; and
at least one switch unit, which can be actuated by a switch signal in order to modify a filter characteristic of the high-frequency filter device by connecting the filter units; and
a signal output, which is configured to output the filtered high-frequency signal.

12. The high-frequency filter device according to claim 11, wherein the at least one switch unit is configured as a microelectromechanical (MEMS) switch unit.

13. The high-frequency filter device according to claim 12, wherein the MEMS switch unit can be actuated electrostatically and/or piezoelectrically by the switch signal.

14. The high-frequency filter device according to claim 12, wherein the MEMS switch unit includes at least one electrode layer, which includes the same material as a layer of the filter units.

15. The high-frequency filter device according to claim 11, wherein the modified filter characteristic is at least one of a passband width, a phase position, and an impedance of the high-frequency filter device.

16. The high-frequency filter device according to claim 11, further comprising a control line, which is configured to receive the externally generated switch signal and to transmit it to the switch unit for actuating the switch unit.

17. The high-frequency filter device according to claim 11, wherein each of the filter units includes at least one of an acoustic resonator, a capacitor, and a resistor.

18. The high-frequency filter device according to claim 11, wherein each of the filter units has a piezo element configured as a multi-layer piezo stack.

19. A high-frequency module, comprising:
at least one high-frequency filter device including:
a signal input which is configured to receive a high-frequency signal,
a plurality of filter units which are configured to filter the high-frequency signal received by the signal input, and
at least one switch unit, which can be actuated by a switch signal in order to modify a filter characteristic of the high-frequency filter device by connecting the filter units, and
a signal output, which is configured to output the filtered high-frequency signal; and
a control unit configured to actuate the switch unit of the high-frequency filter device using the switch signal.

20. A high-frequency filter method, comprising the following steps:
receiving a high-frequency signal;
filtering the high-frequency signal using a plurality of filter units; and
outputting the filtered high-frequency signal;
wherein, by actuating a switch unit by a switch signal, the filter units are connected in such a way that a filter characteristic of the high-frequency filter device is modified.
